(19) United States
(12) Patent Application Publication
(10) Pub. No.: US 2013/0098426 A1
(43) Pub. Date: Apr. 25, 2013

(54) Leveling Device of Concentrated Photovoltaic Module

(71) Applicants: Wen-Fu Chen, New Taipei City (TW); Ke-Han Chen, Tainan City (TW); Guo-Chun Hsu, Taoyuan County (TW); Cheng-Dar Lee, Tainan City (TW)

(72) Inventors: Wen-Fu Chen, New Taipei City (TW); Ke-Han Chen, Tainan City (TW); Guo-Chun Hsu, Taoyuan County (TW); Cheng-Dar Lee, Tainan City (TW)

(73) Assignee: ATOMIC ENERGY COUNCIL-INSTITUTE OF NUCLEAR ENERGY RESEARCH, Taoyuan County (TW)

(21) Appl. No.: 13/280,441

(22) Filed: Oct. 25, 2011

(51) Int. Cl. H01L 31/052

(52) U.S. Cl. 136/246

(57) ABSTRACT

A leveling device for concentrated photovoltaic (CPV) modules rapidly adjusts a height level of CPV modules on a tracking system. The device makes the CPV modules receive most sunlight for outputting maximum power. The device rapidly adjusts the height level of CPV modules, reduces number of nuts required and, thus, shortens the adjusting time even after the CPV modules are installed.

### TECHNICAL FIELD OF THE INVENTION

The present invention relates to a leveling device; more particularly, relates to installing a concentrated photovoltaic (CPV) module with all of solar cell modules on a sunlight tracking system to be adjusted to the same level to receive the most sunlight for generating the greatest amount of energy.

### DESCRIPTION OF THE RELATED ARTS

When a CPV module receives sunlight from a different angle, energy amount thus generated is different, even maybe no power generated. Hence, after a solar cell module is installed on a sunlight tracking system, the solar cell module has to be adjusted at a level for generating greatest amount of energy.

Prior arts of leveling device for the CPV module only provide few adjusting parts with limited range for adjustment, not to mention adjusting each individual solar cell module. Moreover, it takes time to loose and tighten all the nuts for adjustment. Hence, the prior arts do not fulfill all users' requests on actual use.

### SUMMARY OF THE INVENTION

The main purpose of the present invention is to install a CPV module with all solar cell modules on a tracking system to be adjusted to the same level to receive the most sunlight for generating the greatest amount of energy.

The second purpose of the present invention is, by using a tapping structure, to reduce number of nuts to shorten time for leveling.

The third purpose of the present invention is to process adjustment even on the ground without climbing high to the solar cell module.

To achieve the above purposes, the present invention is a leveling device of concentrated photovoltaic module, comprising a plurality of connecting tubes, a plurality of adjusting components, a plurality of adjusting parts and a solar cell module, where the connecting tube has a first hollow and a second hollow; a rib plate is located between the first hollow and the second hollow; a notch is located on an end surface of the rib plate; the connecting tube has a first screw hole and a second screw hole at two ends; the first screw hole and the second screw hole are penetrated through the connecting tube; the adjusting component has a third screw hole, a third hollow, a first embedded slot and two second embedded slots, the third screw hole is penetrated through an end surface of the adjusting component to be connected with the third hollow; the first embedded slot is located on an end surface of the third hollow; the two second embedded slots are located on two end surfaces of each one of the two adjusting components, separately; an opening is located on an end surface of the first embedded slot; the opening connects the first embedded slot and the two second embedded slots; the plurality of adjusting parts penetrates through the connecting tubes and the adjusting components to fasten the adjusting components to the connecting tubes separately; and the solar cell module is fastened to the adjusting components. Accordingly, a novel leveling device of concentrated photovoltaic module is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the view showing the preferred embodiment according to the present invention;

FIG. 2 is the view showing the combination of the adjusting component and the connecting tube;

FIG. 3 is the view showing the area A in FIG. 2;

FIG. 4 is the perspective view showing the connecting tube;

FIG. 5 is the front view showing the connecting tube;

FIG. 6 is the perspective view showing the adjusting component; and

FIG. 7 is the front view showing the adjusting component.

### DESCRIPTION OF THE PREFERRED EMBODIMENT(S)

The following description of the preferred embodiment is provided to understand the features and the structures of the present invention.

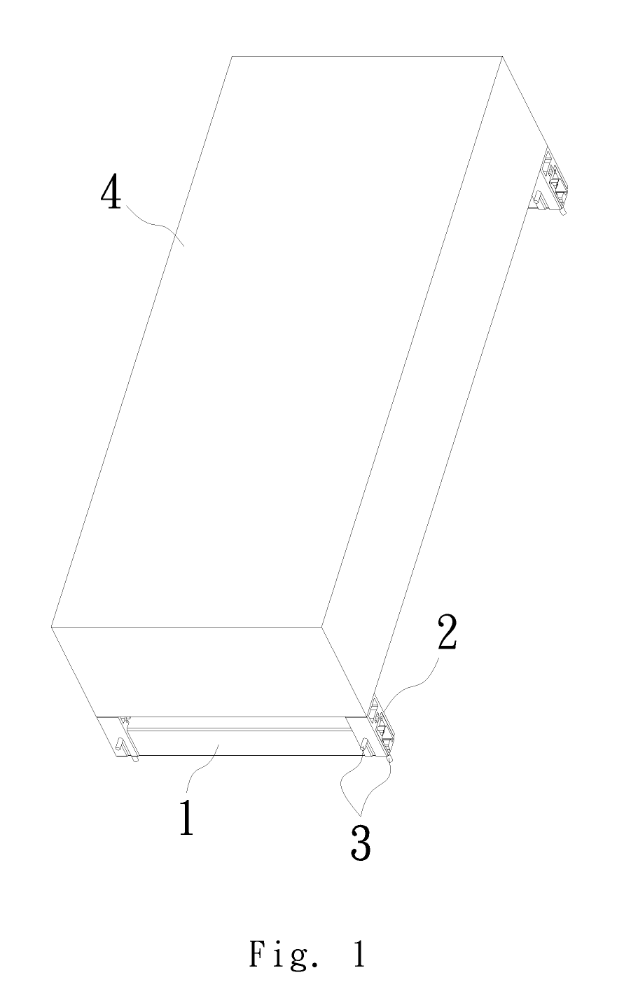

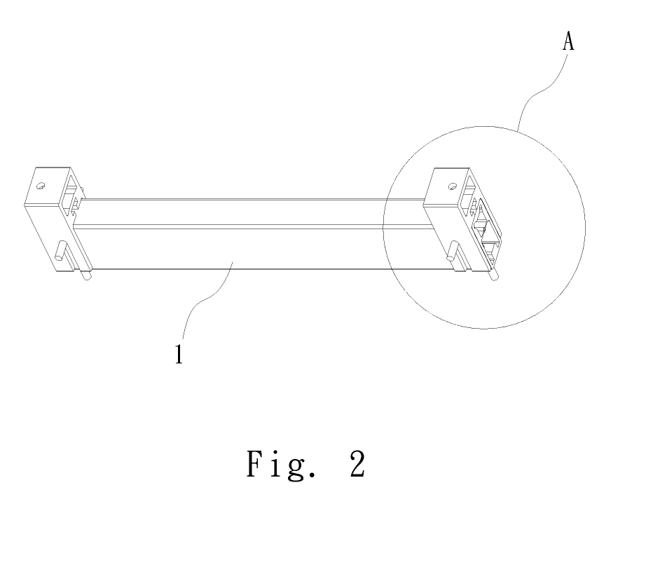

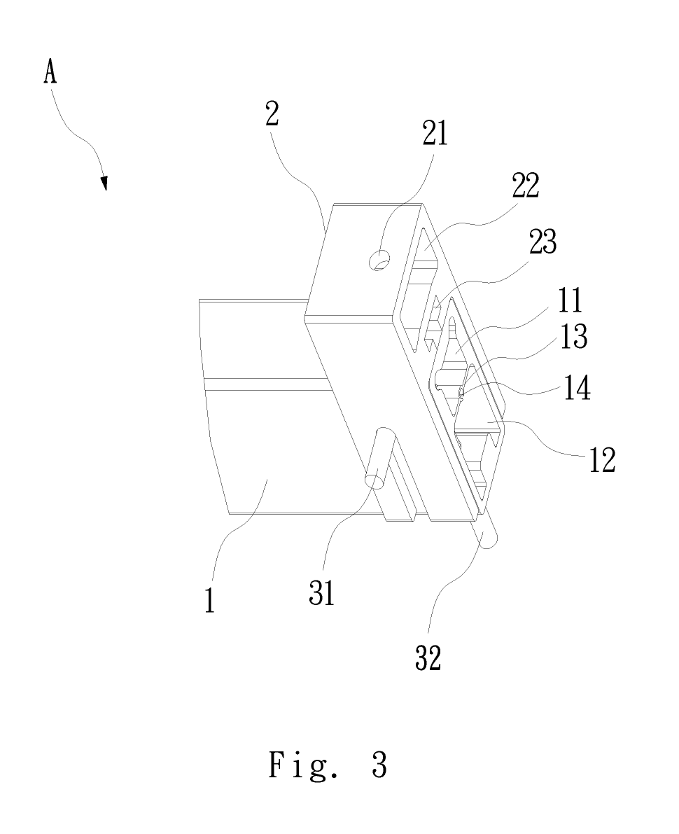

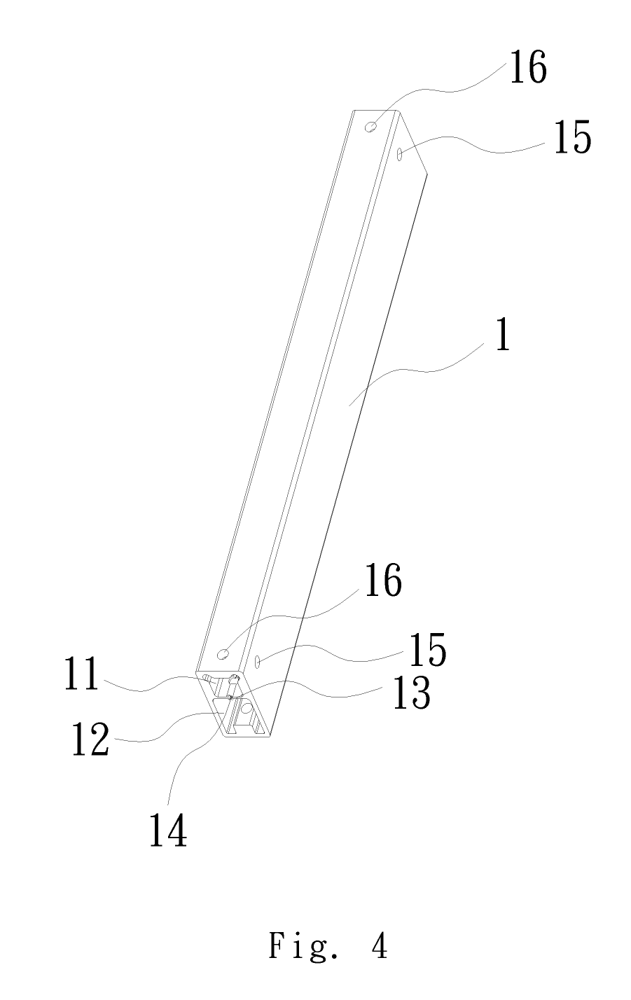

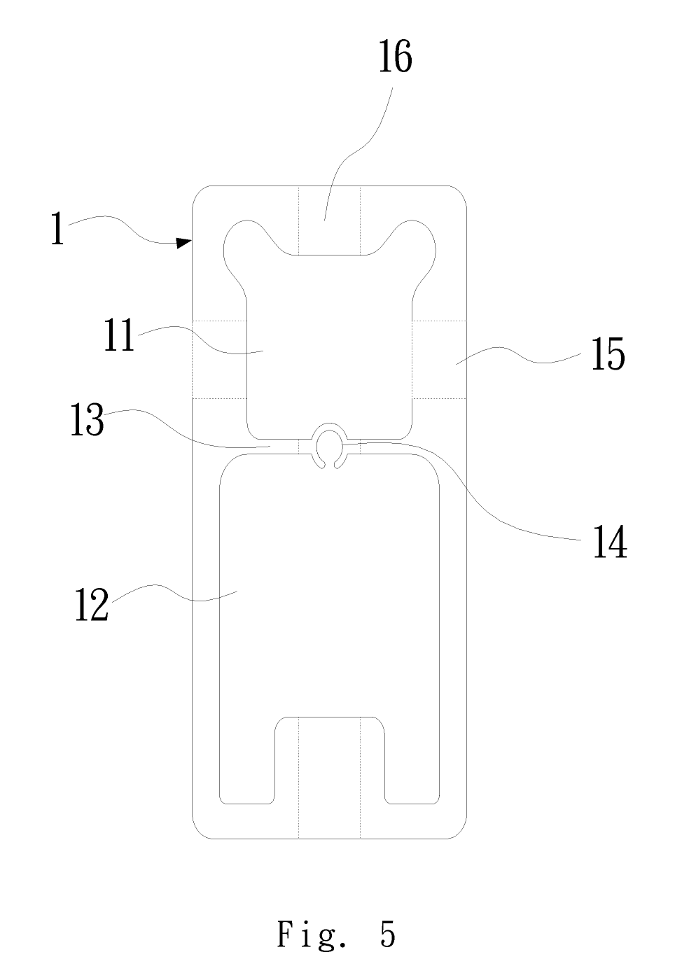

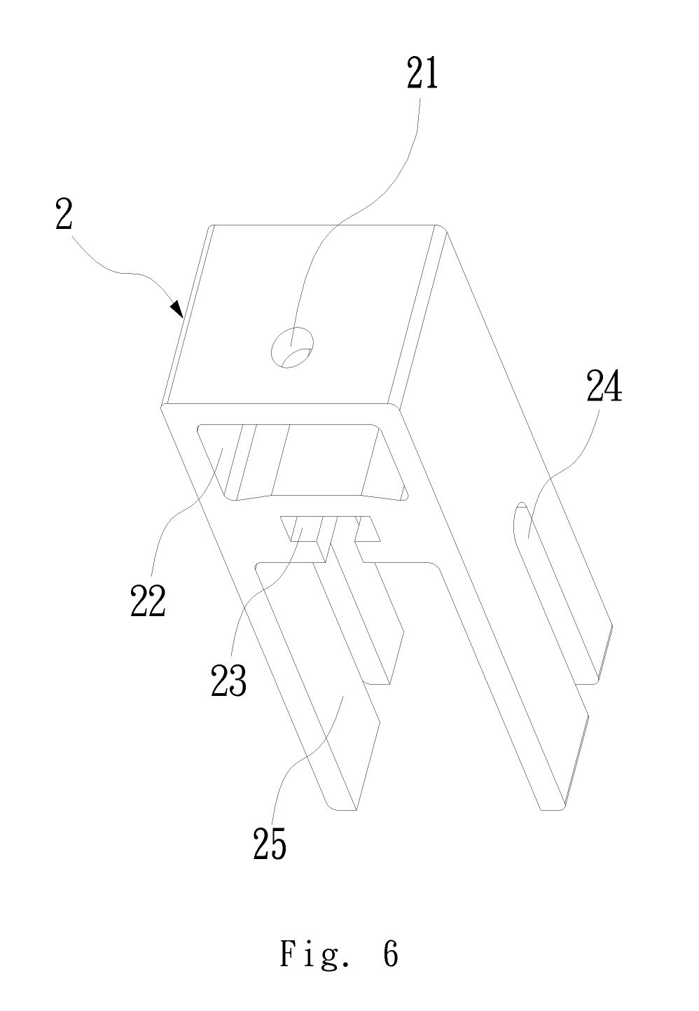

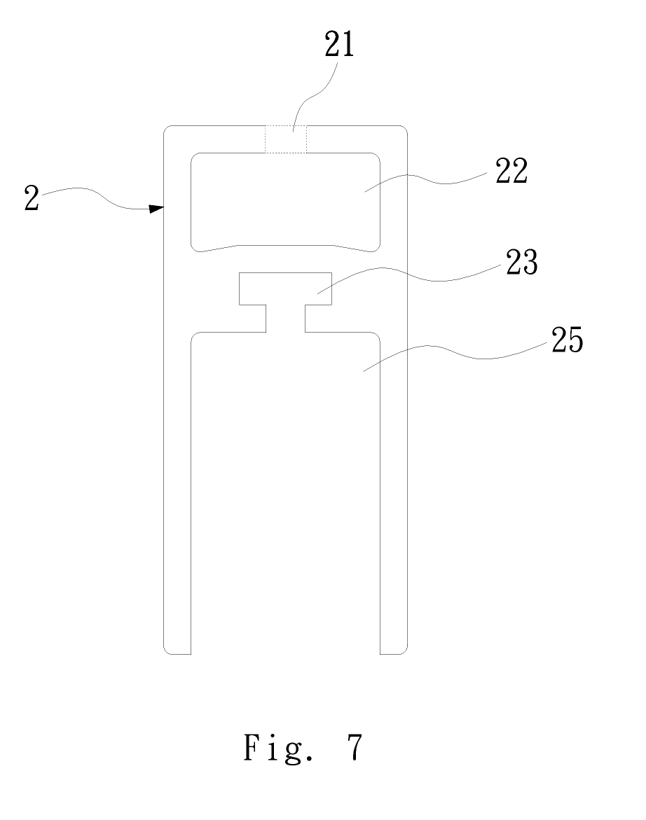

Please refer to FIG. 1 to FIG. 7, which are a view showing a preferred embodiment according to the present invention; a view showing combination of a adjusting component and a connecting tube; a view showing area A in FIG. 2; a perspective view and a front view showing the connecting tube; and a perspective view and a front view showing the adjusting component. As shown in the figures, the present invention is a leveling device of concentrated photovoltaic (CPV) module, comprising a plurality of connecting tubes 1, a plurality of adjusting components 2, a plurality of adjusting parts 3 and a solar cell module 4, where all solar cell modules of a tracing system are adjusted to receive most sunlight for generating greatest amount of energy.

The connecting tube 1 has a first hollow 11 and a second hollow 12, where a rib plate 13 is located between the first and the second hollows 11,12; a notch 14 is located beneath the rib plate 13; each connecting tube 1 has a first screw hole 15 and a second screw hole 16 separately at two ends; the first and the second screw holes 15,16 are penetrated through the connecting tube 1 for connection; the connecting tube 1 is a square tube; the notch 14 has a C shape; the first and the second screw holes 15,16 have a staggered arrangement; the first screw hole 15 is a hole penetrating through the first hollow 11; and the second screw hole 16 is a tapping hole penetrating through the first hollow 11 and the second hollow 12.

The adjusting component 2 has a third screw hole 21, a third hollow 22, a first embedded slot 23 and two second embedded slots 24, where the third screw hole is penetrated through an upper surface of the adjusting component 2 to be connected with the third hollow 22; the first embedded slot 23 is located on a lower surface of the third hollow 22 and has an opening located on a lower surface of the first embedded slot 23 to connect the first embedded slot 23 and the two second embedded slots 24; the second embedded slots 24 are located on two end surfaces of each one of the two adjusting components 2, separately; the first embedded slot 23 has a T shape; and the second embedded slot 24 has a U shape.

The adjusting parts 3 penetrate through the connecting tubes 1 and the adjusting components 2 separately to fasten the adjusting components 2 to the connecting tubes 1, where each of the adjusting parts 3 is a screw selected from a first screw 31 and a second screw 32.

The solar cell module 4 is fixed to the adjusting components 2.

Thus, a novel leveling device of CPV module is obtained.

A positioning platform of solar cell modules (not shown in the figures), comprising two of the connecting tubes 1, is used as a fixing device to fasten the leveling device by the adjusting parts 3. Four of the adjusting components 2 are fixed on the connecting tubes 1 by the first screws 31 and the second screws 32 through the first screw holes 15 and the second screw holes 16. The second screws 32 are positioned at the first embedded slot 1. At last, the solar cell module 4 is fixed on the adjusting components 2 with screws (not shown in the figures) through the third screw holes 21 to finish assembling the leveling device of CPV module. On using the present invention, the first screws 31 are loosed a bit for adjusting the height of the solar cell module 4 by the second screws 32. The second screws 32 are fixed on the screws by pasting an anaerobic adhesive under the second screws 32 for leveling by simply turning the cap nuts of the screws.

The present invention is able to process leveling after installing a solar cell module. By using a tapping structure, number of nuts is reduced to shorten time for leveling. Thus, leveling adjustment is rapidly done after installing a solar cell module, even on the ground without climbing high to the solar cell module, where the solar cell module is adjusted at the same level for generating the greatest amount of energy.

To sum up, the present invention is a leveling device of CPV module, where a CPV module is installed with all solar cell modules on a tracking system to be adjusted to the same level to receive the most sunlight for generating the greatest amount of energy.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A leveling device of concentrated photovoltaic (CPV) module, comprising
a plurality of connecting tubes,
wherein each one of said connecting tubes has a first hollow and a second hollow;
wherein a rib plate is located between said first hollow and said second hollow;
wherein a notch is located on an end surface of said rib plate;
wherein each one of said connecting tubes has a first screw hole and a second screw hole at two ends of said one of said connecting tubes; and
wherein said first screw hole and said second screw hole are penetrated through said one of said connecting tubes;
a plurality of adjusting components, each one of said adjusting components having a third screw hole, a third hollow, a first embedded slot and two second embedded slots,
wherein said third screw hole is penetrated through an end surface of said adjusting component to be connected with said third hollow;
wherein said first embedded slot is located on an end surface of said third hollow;
wherein said two second embedded slots are located on two end surfaces of each one of said adjusting components, separately;
wherein an opening is located on an end surface of said first embedded slot; and
wherein said opening connects said first embedded slot and said two second embedded slots;
a plurality of adjusting parts, said plurality of adjusting parts penetrating through said connecting tubes and said adjusting components to fasten said adjusting components to said connecting tubes, separately; and
a solar cell module, said solar cell module being fastened to said adjusting components.

2. The leveling device according to claim 1, wherein said connecting tube is a square tube.

3. The leveling device according to claim 1, wherein said notch has a C shape.

4. The leveling device according to claim 1, wherein said first screw hole and said second screw hole have a staggered arrangement.

5. The leveling device according to claim 1,
wherein said first screw hole is a hole penetrating through said first hollow.

6. The leveling device according to claim 1,
wherein said second screw hole is a tapping hole penetrating through said first hollow and said second hollow.

7. The leveling device according to claim 1,
wherein said first embedded slot has a T shape.

8. The leveling device according to claim 1,
wherein said second embedded slot has a U shape.

9. The leveling device according to claim 1,
wherein said adjusting part is a screw.

10. The leveling device according to claim 1,
wherein said leveling device further comprises a fixing device fastened to said leveling device by said adjusting parts.
